(19) United States
(12) Patent Application Publication
(10) Pub. No.: US 2010/0294345 A1
(43) Pub. Date: Nov. 25, 2010

(54) SOLAR MODULE FASTENING SYSTEM

(75) Inventors: Walter Leithold, Freiburg (DE); Martin Siebert, Freiburg (DE)

Correspondence Address: VOLPE AND KOENIG, P.C., UNITED PLAZA, 30 SOUTH 17TH STREET, PHILADELPHIA, PA, 19103, US

(73) Assignee: SOLARMARKT AG, Freiburg (DE)

(21) Appl. No.: 12/864,393

(22) PCT Filed: Jun. 3, 2008
(86) PCT No.: PCT/EP08/04399

§ 371 Date: Jul. 23, 2010

(30) Foreign Application Priority Data
Jan. 25, 2008 (DE) 10 2008 006 106.9

(51) Int. Cl. H01L 31/048

(52) U.S. Cl. 136/251

(57) ABSTRACT

A solar module fastening system including a stationary or moveably supported carrier, on which the solar modules (3) are arranged. The fastening system provides that the carrier has at least one carrier profile (2) and that at least one counter profile (5) that can be inserted into the carrier profile (2) is arranged on the solar module (3).

### BACKGROUND

The invention relates to a solar-module fastening system with a stationary or movably supported carrier on which the solar modules are arranged.

Solar-module fastening systems often have a stationary or movably supported carrier, in order to mount the solar modules, in particular, photovoltaic modules, at an angle to solar irradiation. Here, for example, profile rails onto which the solar modules are screwed are arranged on the frame.

The assembly of the solar modules is complicated accordingly, because for each solar module several screws must be attached. In particular, frame-less solar modules must first be provided with mounts that can be screwed on. Due to the mounts that are usually attached at points, stresses are produced in the glass that can lead to cracks in the solar module during assembly or during system operation.

### SUMMARY

The objective of the invention is therefore to create a solar-module assembly system that allows a simple, quick, and secure assembly of arbitrary solar modules.

This objective is met in that the carrier has at least one support profile. In addition, at least one counter profile that can be inserted into the carrier profile is arranged on the solar module.

Therefore, because the counter profile can be inserted into the carrier profile, the assembly of the solar modules can be performed without screws and tools and thus more quickly and more easily. In addition there is no risk of stress fractures being formed in the solar module, which means there is no risk of breakage during assembly and the solar modules can be mounted reliably.

The counter profiles can be arranged arbitrarily on the back side of the solar module, so that a structurally optimal support can be guaranteed even for large solar modules. Therefore, in comparison with in-lay systems according to the prior art, any solar modules for an in-lay system could be used.

The profiles can here be constructed approximately so that the counter profiles are pushed in, suspended on, or set in the carrier profiles and for this purpose are advantageously constructed essentially with an H-shaped, T-shaped, or C-shaped form. The carrier profile here can have the same shape or also a different shape than the counter profile.

One construction of the invention provides that a solar module is fastened with two profile pairs each formed from a carrier profile and a counter profile, wherein the counter profiles are each arranged offset approximately 20% of the solar-module length inward from the solar-module edge. According to the size of the solar module, other distances could also be useful, in order to guarantee a secure support.

In this way it is also possible to arrange the counter profiles on the edge of the solar module. In particular, for the use of framed solar modules, the counter profiles can be fastened, advantageously, screwed, directly on the solar-module frame.

Independent of the position of the two profile pairs, according to the size of the solar module or for special structural requirements between the two profile pairs, a third profile pair, optionally also additional profile pairs, could be provided. The distances between the individual profile pairs can advantageously be selected to be equidistant, in order to attain a uniform load distribution.

A different construction of the invention provides a three-point fastening of a solar module, wherein the solar module is fastened at opposite edges with in-lay profiles according to the prior art and a middle support is realized with a profile pair according to the invention.

Another construction of the invention provides, for example, H-shaped carrier profiles in which a counter profile can be inserted on both sides, wherein the counter profile is arranged on the edge of a solar module. Therefore, the number of required carrier profiles is almost halved, because two solar modules can be inserted in each carrier profile.

The carrier profiles can be constructed as continuous profiles and can extend across the full width of a solar module. It is also possible to mount several solar modules on a continuous carrier profile. The carrier profiles, however, can also be constructed as individual profile sections, wherein an arbitrary number of profile sections can be used for one solar module.

Independent of this, it is also possible to construct the counter profiles continuously, so that a counter profile has the width of a solar module. The counter profiles, however, can also be constructed only in sections.

Another variant provides fastening several solar modules on a continuous or section-by-section counter profile. In this way it is possible to first create an assembly unit from several solar modules, wherein this unit can then be mounted with little effort.

The assembly system according to the invention can be used in an especially advantageous way with frame-less solar modules. The counter profiles can here be already assembled by the manufacturer and can be inserted directly into the carrier profiles, so that no additional work on the modules must be performed by the user. Therefore, the risk of breakage of the frame-less modules is also reduced, and the safety during assembly as well as the assembly speed are increased.

The counter profiles are preferably adhered with the frame-less solar module, which can be performed already by the manufacturer or also by the user. Through the use of permanently elastic adhesives, it can be simultaneously prevented that temperature-dependent, mechanical stresses in the carrier profile are transmitted to the glass of the solar module.

The assembly system, however, can be used in the same way for framed solar modules in which the counter profiles can be screwed to the already provided module frame. Thus, on one hand, the simple assembly with plug-in profiles is possible, and on the other hand, the assembly defaults of the manufacturer can be maintained. With this method, the advantages of the in-lay principle also come to bear in assembly situations in which, for example, due to high snow loads, structural reasons speak against fastening only at the short module edges.

In an especially advantageous way, the profiles can be constructed so that an essentially positive-fit engagement of the counter profile in the carrier profile is realized. In particular, it is possible that the counter profile locks in the carrier profile. Here, it can be useful when catch or securing elements are provided on the profiles, wherein these elements prevent the solar modules from being simply lifted out from the profiles, in particular, due to suction caused by wind at the top side of the solar modules. In this way, the solar modules can also be mounted at a minimal inclination angle up to horizontal.

Through a suitable formation of the profiles, it is likewise possible to produce a height offset between the module top edge and module bottom edge, which can provide better ventilation or can be desirable for aesthetic reasons.

Due to the profile-in-profile assembly according to the invention, for a corresponding arrangement of the solar modules on the profiles, especially with frame-less modules, it is possible to create a continuous surface without visible intermediate spaces from several solar modules.

An especially useful construction of the invention provides an anti-theft safety device in which the outlet path is blocked on the inlet side of the carrier profiles.

### BRIEF DESCRIPTION OF THE DRAWINGS

Additional, advantageous constructions and features of the invention are given from the dependent claims and the embodiments that are explained in detail below with reference to the drawings.

Shown are:

FIG. 1 a cross-sectional view of a solar-module arrangement with a first arrangement of the solar-module fastening system according to the invention,

FIG. 2 a cross sectional view of a carrier profile according to the invention,

FIG. 3 a cross sectional view of a counter profile according to the invention,

FIG. 4 a cross-sectional view of a solar-module arrangement with a second arrangement of the solar-module fastening system according to the invention,

FIG. 5 a detail view of a solar-module arrangement, and

FIG. 6 a cross-sectional view of a solar-module arrangement with a third arrangement of the solar-module fastening system according to the invention.

### DETAILED DESCRIPTION OF THE PREFERRED EMBODIMENTS

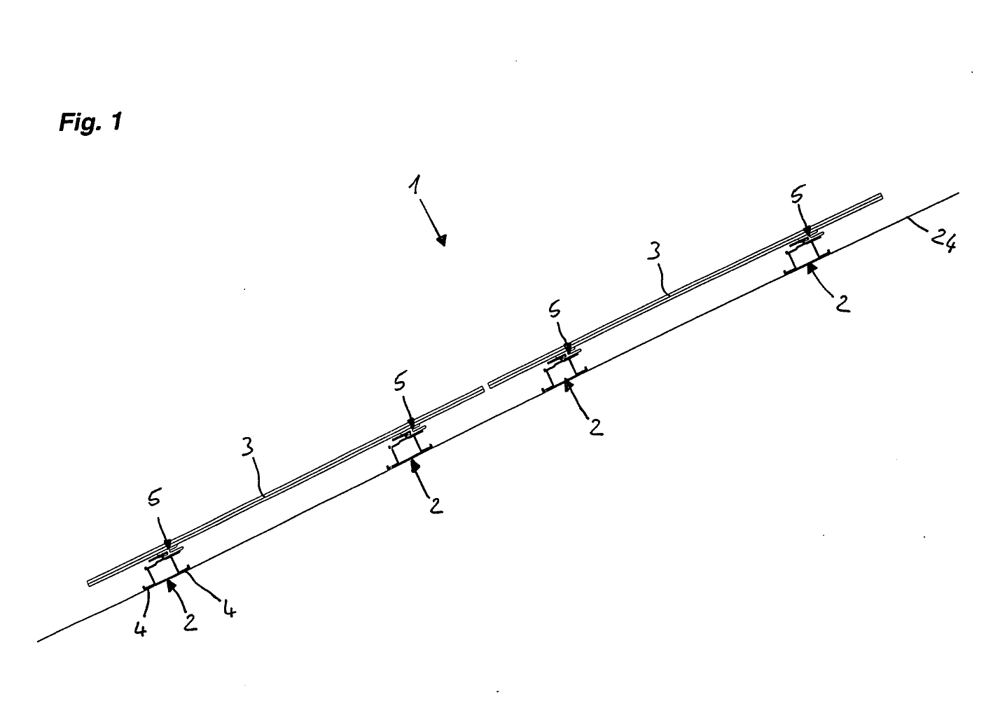

FIG. 1 shows a solar module designated as a whole with 1. For example, H-shaped carrier profiles 2 for fastening the solar modules 3 are arranged on a sub-structure 24, for example, a suitable support structure or a building roof. The carrier profiles 2 have fastening flanges 4 on which the carrier profiles 2 are fastened to the sub-structure 24, for example, by screws or rivets.

Two, for example, H-shaped counter profiles 5 are arranged on the solar modules 3 for engaging in the corresponding carrier profiles 2. The counter profiles 5 are here fastened offset for example 20% of the solar-module length inward from the edge.

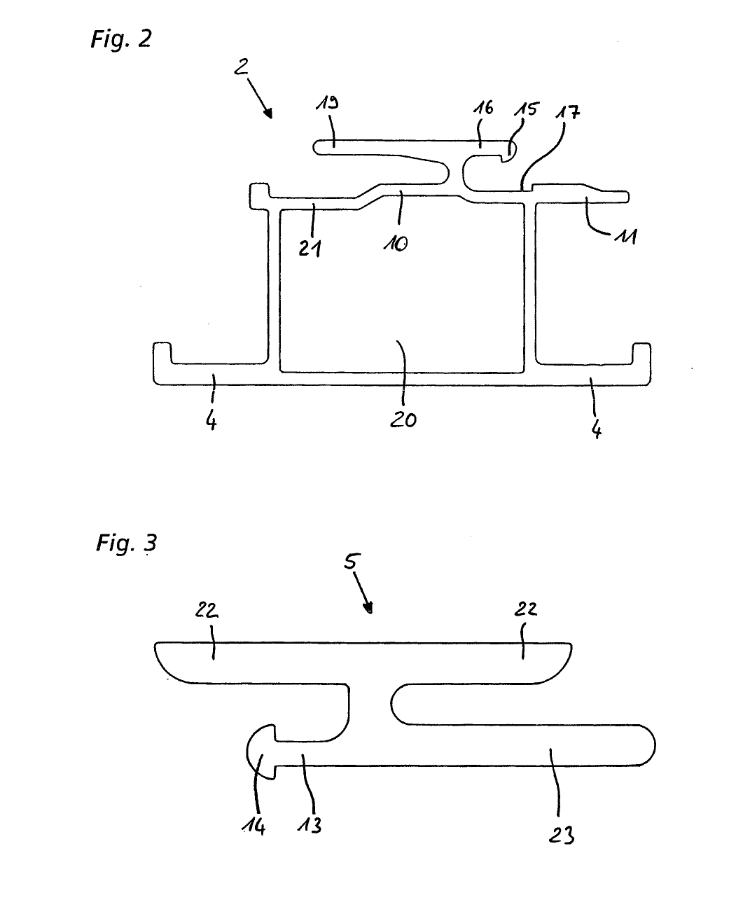

The counter profiles 5 are each arranged so that the solar module 3 can be simply suspended. Here, each counter profile 5 can be set with its anchor flange 13 on the support flange 11 of the carrier profile 2 and can then be pushed downward (FIGS. 2 and 3). The anchor flange 13 of the counter profile 5 has an anchor-shaped formation 14 that creates an essentially positive-fit connection of the profiles 2, 5 together with a retaining tab 15 on the retaining flange 16 and a projection 17 on the support flange 11 of the carrier profile 2, so that the counter profile 5 locks in the carrier profile 2 when the solar module 3 is pushed into an engagement position.

The retaining tab 15 here prevents the solar module 3 from being able to be pushed out from the carrier profile 2 after, for example, it has been lifted by a wind gust. Likewise, the projection 17 prevents the solar module 3 from being able to be pushed back and lifted from engagement without resistance.

In FIG. 2, a construction of a carrier profile 2 according to the invention is shown. The carrier profile 2 has an essentially H-shaped construction and has an insertion flange 19, a retaining flange 16, and two support flanges 10, 11. The carrier profile also has a rectangular hollow chamber 20 under the support flanges 10, 11 and two fastening flanges 4 that are arranged on the boundary wall of the hollow chamber 20.

The insertion flange 19 is completely rounded on its end and has a longer construction in comparison with the retaining flange 16, in the illustrated example, approximately three times as long. The retaining flange 16 has an inwardly directed retaining tab 15 that is likewise rounded on the end. The support flange 10 on the insertion-flange side of the carrier profile 2 has an insertion recess 21 that is needed for the inclined insertion of a counter profile 5. At approximately the height of the retaining tab 15, the other support flange 11 has a projection 17 that allows, together with the retaining tab 15, an essentially positive-fit locking of a counter profile 5.

The fastening flanges 4 are provided for fastening the carrier profile 2 on a sub-structure 24. Here, several types of fastening devices are known to someone skilled in the art, wherein, in addition to screws, rivets, or welding, these types can be selected according to the requirements and material. For a more compact construction of the carrier profile according to the invention without a hollow chamber 20, the fastening can also be realized on the support flanges 10, 11.

The counter profile 5 shown in FIG. 3 likewise has an essentially H-shaped construction and has two adhesive flanges 22 that are provided for fastening the counter profile 5 on a solar module 2 and are rounded on their inner edge. Furthermore, the counter profile 5 has an anchor flange 13 on which an anchor-shaped formation 14 is provided for engaging in the retaining flange 16 of a carrier profile 2, wherein the anchor flange 13 is shorter than the adhesive flanges 22. The insertion flange 23 of the counter profile 5, in contrast, is longer than the other counter-profile flanges 13, 22 and is completely rounded on its end.

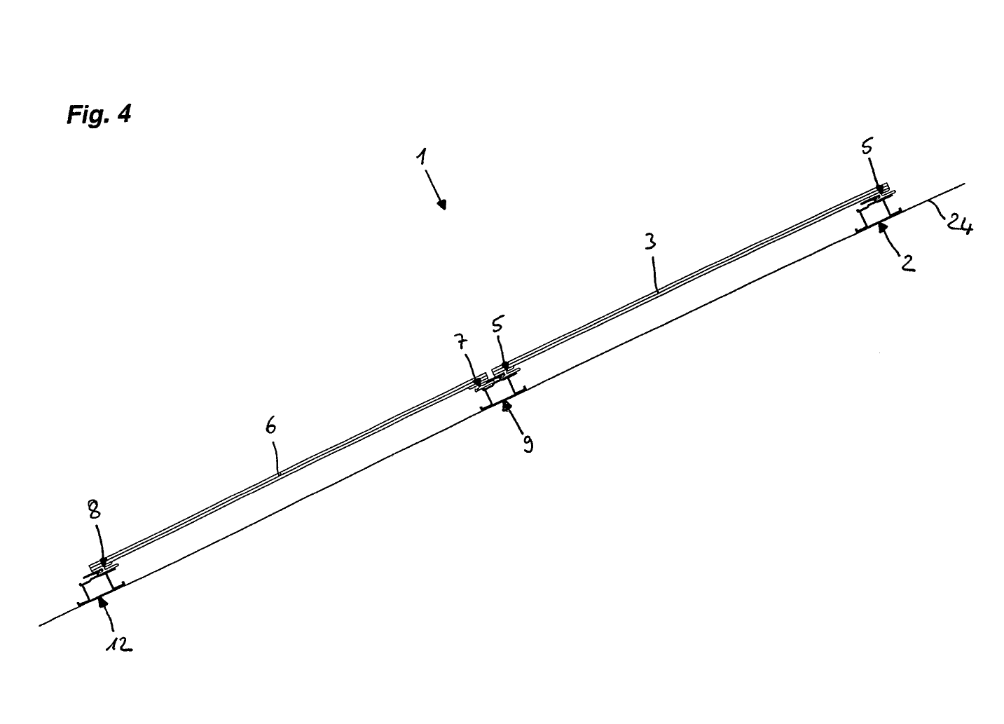

The solar-module arrangement shown in FIG. 4 differs from that shown in FIG. 1 in that the carrier profiles are arranged essentially between two solar modules, so that a counter profile is inserted into the H-shaped carrier profile on both sides.

For assembly, the solar module 6 with the counter profiles 7, 8 is inserted into the corresponding carrier profile 9 first from above, slightly at an angle with the counter profile 7 located on the solar module on the right in the figure. The counter profile 8 located on the solar module on the left in the figure is then lowered, so that the counter profiles 7, 8 lie on the support flanges 10, 11 of the carrier profiles 9, 12. The solar module 6 with the counter profiles 7, 8 is then pushed along the solar-module plane in the direction of the second carrier profile 12 into an engagement position in which the anchor-shaped formation 14 of the anchor flange 13 engages in the retaining flange 16 approximately with a positive-fit connection, wherein the retaining tab 15 prevents a simple sliding from the engagement position.

The second solar module 3 is suspended according to the construction shown in FIG. 1.

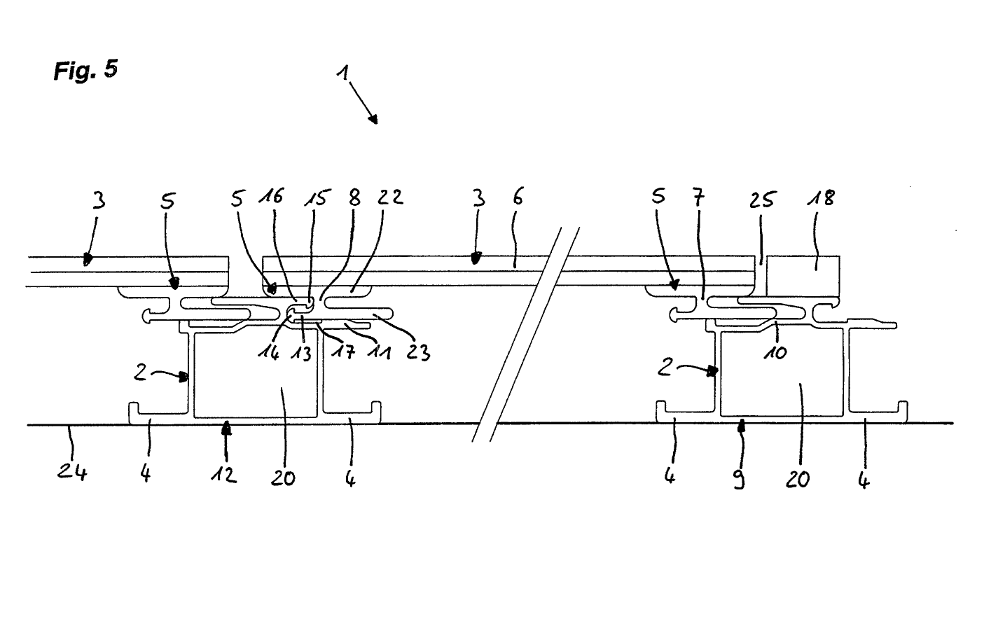

FIG. 5 shows a detailed view of a solar-module arrangement 1, wherein here two visible solar modules 3 according to the second variant are pushed into the carrier profiles 2. At the edge of the solar-module arrangement, an end strip 18 is set on the carrier profile 2. Here, the end strip 18 is fastened close to the adjacent solar module 2, so that the remaining gap 25 is too short for shifting the solar module 2 out from the engagement position. The end strip 18 can also be equipped with an anti-theft safety device, for example, a padlock, in order to prevent unlawful removal of the solar modules from the arrangement.

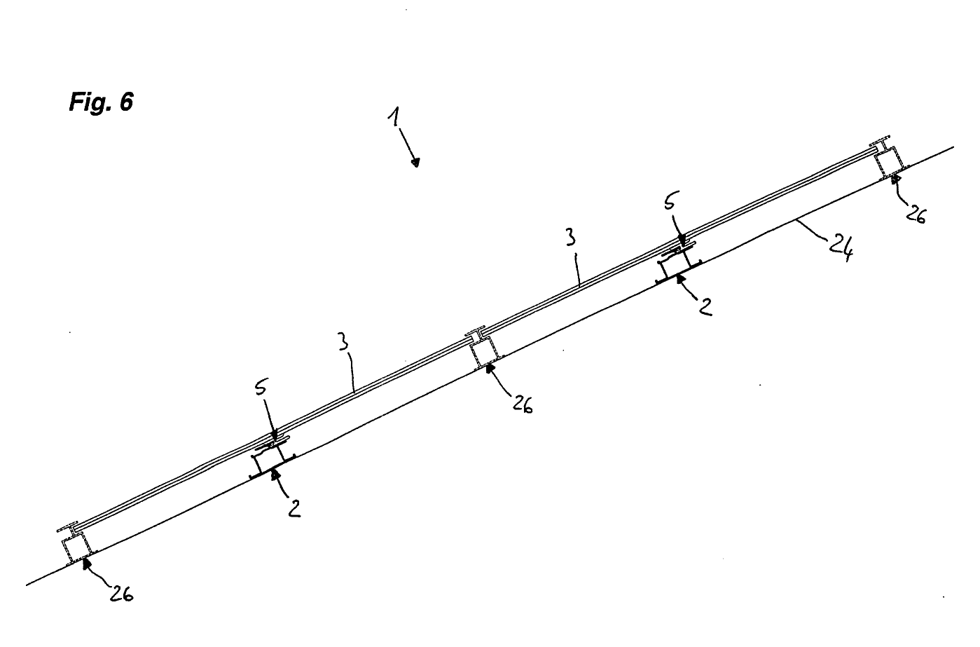

FIG. 6 shows another construction of the invention, wherein the solar module is fastened on two opposite sides with an arbitrary in-lay system 26 according to the prior art. Such in-lay systems 26 are adequately known, so that their function is not explained here in detail. In this construction, the use of a profile pair 2, 5 according to the invention as a middle support is novel.

In this arrangement, the solar module is likewise first inserted on one side at an angle into an in-lay profile, in the shown example, the right profile. Then the profile is lowered and pushed to the left in the example. Therefore, both the solar-module end is inserted into the second in-lay profile and the counter profile arranged approximately in the middle engages in the carrier profile. In particular, for large solar modules, a structurally required middle support could be realized in this way. Obviously, more than one middle support could also be provided if this is necessary or advantageous.

Deviating from the shown embodiments, for the assembly system according to the invention, other profile shapes are also conceivable that allow an essentially positive-fit engagement of the counter profiles into the carrier profiles.

Therefore, instead of the H-shaped profiles, T-shaped or C-shaped profiles are also conceivable, wherein, for the carrier and counter profiles, different profile shapes could also be provided, as long as corresponding catch or securing elements are provided for the positive-fit engagement or locking.

1. Solar-module fastening system comprising a stationary or movably supported carrier (24) on which solar modules (3) are arranged, the carrier (24) has at least one carrier profile (2) and at least one counter profile (5) is insertable into the carrier profile (2) and is arranged on the solar module (3).

2. Solar-module fastening system according to claim 1, wherein the counter profile (5) is insertable into the carrier profile (2) essentially with a positive-fit connection.

3. Solar-module fastening system according to claim 2, wherein catch or securing elements (14, 15, 17) that allow the essentially positive-fit connection between the carrier profile (2) and the counter profile (5) are provided on the profiles (2, 5).

4. Solar-module fastening system according to claim 1, wherein at least one of the counter profile (5) or the carrier profile (2) has essentially an H-shaped, T-shaped, or C-shaped form.

5. Solar-module fastening system according to claim 1, wherein at least one of the carrier profile (2) or the counter profile (5) is constructed as a continuous profile rail.

6. Solar-module fastening system according to claim 1, wherein at least one of the carrier profile (2) or the counter profile (5) are constructed as individual profile sections.

7. Solar-module fastening system according to claim 1, wherein several of the solar modules (3) are combined into a module assembly unit by at least two of the counter profiles (5).

8. Solar-module fastening system according to claim 1, wherein for each of the solar modules (3), two profile pairs each made from one of the carrier profiles (2) and one of the counter profiles (5) are provided and the counter profiles are arranged offset approximately 20% of a solar-module length inward from an edge of the solar module.

9. Solar-module fastening system according to claim 8, wherein at least one additional profile pair is provided as a middle support between the two edge profile pairs.

10. Solar-module fastening system according to claim 1, wherein the counter profile (5) is fastened on the solar module (3) by a manufacturer.

11. Solar-module fastening system according to claim 1, wherein the counter profile (5) is adhered onto the solar module (3) with a permanently elastic adhesive.

12. Solar-module fastening system according to claim 1, wherein the counter profile (5) is screwed, riveted, or fastened permanently onto a frame of the solar module (3).

13. Solar-module fastening system according to claim 1, wherein at least one of the carrier profile (2) or the counter profile (5) is manufactured from aluminum.

14. Solar-module fastening system according to claim 1, wherein the carrier profile (2) has at least one fastening flange (4) or a fastening groove for permanent assembly on a sub-structure (24).

15. Solar-module fastening system according to claim 1, wherein an anti-theft safety device is provided that prevents the counter profile (5) from being released from engagement in the carrier profile (2).
